(19) United States
(12) Patent Application Publication
(10) Pub. No.: US 2024/0352581 A1
(43) Pub. Date: Oct. 24, 2024

(54) ATOMIC LAYER DEPOSITING APPARATUS AND ATOMIC LAYER DEPOSITING METHOD USING THE SAME

(71) Applicant: NEXUSBE CO., LTD, Jeonju-si Jeollabuk-do (KR)

(72) Inventors: Hag Young CHOI, Yongin-si Gyeonggi-do (KR); Dong Won KIM, Yongin-si Gyeonggi-do (KR); Sang Hun KIM, Gwangju-si Gyeonggi-do (KR); Keun Sik KIM, Yongin-si Gyeonggi-do (KR)

(73) Assignee: NEXUSBE CO., LTD, Jeonju-si Jeollabuk-do (KR)

(21) Appl. No.: 18/755,892

(22) Filed: Jun. 27, 2024

Related U.S. Application Data
(63) Continuation of application No. PCT/KR2022/010333, filed on Jul. 15, 2022.

(30) Foreign Application Priority Data
Dec. 29, 2021 (KR) 10-2021-0190716

(51) Int. Cl. C23C 16/44; C23C 16/455

(52) U.S. Cl. CPC C23C 16/4408; C23C 16/45551; C23C 16/45561; C23C 16/45589

(57) ABSTRACT

An atomic layer depositing apparatus includes: a gas supply assembly configured to supply a source gas, a reaction gas, and a purge gas; and a substrate transfer module disposed on a lower side of the gas supply assembly, configured to move linearly, and having an upper side on which the substrate is seated. The gas supply assembly includes: a purge gas supply module connected to a purge gas supply line in which the purge gas flows, a reaction gas supply module connected to a reaction gas supply line in which the reaction gas flows, a source gas supply module configured to selectively communicate with any one of the purge gas supply line and a source gas supply line in which the source gas flows, a pumping module disposed among the purge gas supply module, the reaction gas supply module, and the source gas supply module.

### CROSS-REFERENCE TO RELATED APPLICATION

This application is a continuation of International Application No. PCT/KR2022/010333 filed on Jul. 15, 2022, which claims priority to Korean Patent Application No. 10-2021-0190716 filed on Dec. 29, 2021, the entire contents of which are herein incorporated by reference.

### TECHNICAL FIELD

The present disclosure relates to an atomic layer depositing apparatus and an atomic layer depositing method using the same.

### BACKGROUND ART

In general, as a method for depositing a thin film with a predetermined thickness on a substrate, such as semiconductor substrate or glass, there may be physical vapor deposition (PVD) using physical collision, such as sputtering, and chemical vapor deposition (CVD) using chemical reaction.

Recently, as the design rule of a semiconductor device is rapidly becoming more detailed, a thin film of a micro pattern is required, a step in an area where the thin film is formed is getting very large, and thus the use of atomic layer deposition (ALD), which not only can form a micro pattern with an atomic layer thickness very uniformly but also has an excellent step coverage, is increasing.

### DISCLOSURE

### Technical Problem

According to embodiments of the present disclosure, it is intended to provide an atomic layer depositing apparatus and an atomic layer depositing method using the same, which can deposit an atomic layer of a high quality on a substrate.

### Technical Solution

An atomic layer depositing apparatus according to one aspect of embodiments of the present disclosure includes: a gas supply assembly configured to supply a source gas, a reaction gas, and a purge gas; and a substrate transfer module disposed on a lower side of the gas supply assembly, configured to move linearly, and having an upper side on which the substrate is seated, wherein the gas supply assembly includes: a purge gas supply module connected to a purge gas supply line in which the purge gas flows, a reaction gas supply module connected to a reaction gas supply line in which the reaction gas flows, a source gas supply module configured to selectively communicate with any one of the purge gas supply line and a source gas supply line in which the source gas flows, a pumping module disposed among the purge gas supply module, the reaction gas supply module, and the source gas supply module, and configured to provide negative pressure, and a valve module configured to make the source gas supply module connected to any one of the purge gas supply line and the source gas supply line and blocked from the other thereof, wherein the valve module is configured to: (1) connect the source gas supply module and the source gas supply line to each other in case that the substrate is disposed on the side of the source gas supply module, and (2) connect the source gas supply module and the purge gas supply line to each other in case that the substrate is not disposed on the side of the source gas supply module.

Further, the purge gas supply module may include a first side purge gas supply module and a second side purge gas supply module disposed on one side and the other side of the gas supply assembly, respectively, based on a first direction that is a transfer direction of the substrate, and main purge gas supply modules disposed between the reaction gas supply module and the source gas supply module, wherein a plurality of source gas supply modules and a plurality of reaction gas supply modules may be provided to be disposed alternately.

Further, the main purge gas supply module may include a first main purge gas supply unit and a second main purge gas supply unit connected to the purge gas supply line, respectively, wherein the first main purge gas supply unit and the second main purge gas supply unit may be spaced apart from each other based on the first direction, and the pumping module may be disposed between the first main purge gas supply unit and the second main purge gas supply unit.

Further, a side purge module may include a side purge gas supply unit from which the purge gas is discharged, wherein a first supply pressure of the purge gas that is supplied from the side purge gas supply unit may be formed differently from a second supply pressure of the purge gas that is supplied from the main purge gas supply unit, and wherein the second supply pressure may be constant regardless of movement of the substrate, and wherein the first supply pressure may be varied in accordance with a location of the substrate.

Further, any one of the reaction gas supply modules may be disposed between the main purge gas supply module adjacent to the first side purge gas supply module among the plurality of main purge gas supply modules and the first side purge gas supply module, wherein the other of the reaction gas supply modules may be disposed between the main purge gas supply module adjacent to the second side purge gas supply module among the plurality of main purge gas supply modules and the second side purge gas supply module, and the substrate transfer module may selectively move in accordance with any one of the first direction and a second direction that is a direction opposite to the first direction.

Further, between a first source gas supply module that is any one of the source gas supply modules and a second source gas supply module that is the other of the source gas supply modules, the pumping modules, the main purge gas supply modules, and the reaction gas supply modules may be disposed, and may be disposed in the order of “the pumping module—the main purge gas supply module—the pumping module—the reaction gas supply module—the pumping module—the main purge gas supply module—the pumping module”.

Further, the source gas may include a first source gas and a second source gas having a different material from the first source gas, wherein the first source gas supply module may be selectively connected to a first source gas supply line for supplying the first source gas, and wherein the second source gas supply module may be selectively connected to a second source gas supply line for supplying the second source gas.

Further, the first source gas supply module may include a first sub first source gas supply module for supplying the first source gas and a second sub first source gas supply module, wherein the first sub first source gas supply module and the second sub first source gas supply module may be spaced apart from each other in the first direction, and wherein between the first sub first source gas supply module and the second sub first source gas supply module, the pumping modules, the main purge gas supply modules, and the reaction gas supply modules may be disposed, and may be disposed in the order of “the pumping module—the main purge gas supply module—the pumping module—the reaction gas supply module—the pumping module—the main purge gas supply module—the pumping module”.

Further, the same reaction gas may be supplied to the plurality of reaction gas supply modules, and the same purge gas may be supplied to the plurality of purge gas supply modules.

Further, a source gas deposition space may be formed between any one of the purge gas supply modules that is disposed in front of any one of the source gas supply modules and the other of the purge gas supply modules that is disposed in the rear of the other of the source gas supply modules based on the first direction, wherein if one side of the substrate enters the source gas deposition space, the valve module may be controlled so that the source gas supply module that corresponds to the source gas deposition space supplies the source gas, and wherein if the other side of the substrate secedes from the source gas deposition space, the valve module may be controlled so that the source gas supply module that corresponds to the source gas deposition space supplies the purge gas.

Further, the apparatus may further include a valve module controller for controlling the valve module, wherein the valve module controller may be configured to control an operation of the valve module based on at least one of a location in the first direction of the substrate transfer module, a location where the substrate is disposed on the substrate transfer module, and a transfer speed of the substrate transfer module.

Further, a plurality of source gas deposition spaces may be formed and disposed to be spaced apart from each other in the first direction, wherein in case that a plurality of substrates are located in a deposition space that is formed on a lower side of the gas supply module, the source gas supply module in the source gas deposition space in which the substrates are located may be configured to supply the source gas into the source gas deposition space, and the source gas supply module in the source gas deposition space in which the substrates are not located may be configured to supply the purge gas into the source gas deposition space.

Further, the reaction gas supply module and the purge gas supply module may be configured to continuously supply the reaction gas and the purge gas regardless of the location of the substrate.

Further, a purge space in which the purge gas is supplied to the substrate may be formed between the reaction gas supply module and the source gas supply module that is adjacent to the reaction gas supply module, and the purge space may be formed larger than the source gas deposition space based on the first direction.

Further, the valve module may include a bypass line having one side connected to the source gas supply line and the other side connected to the purge gas supply line, a first valve unit disposed on the bypass line, and a second valve unit disposed on the source gas supply line, wherein the second valve unit may be disposed between a point where the source gas supply line and the bypass line are connected to each other and a source gas storage in which the source gas is stored.

Further, the source gas supply line and the purge gas supply line may be connected to each other, wherein the valve module may be installed at a point where the source gas supply line and the purge gas supply line are connected to each other, and may be configured to make any one of the gases be selectively supplied to the side of the source gas supply module.

Further, the apparatus may further include a plasma oscillator configured to ionize the reaction gas, wherein the plasma oscillator may be connected to any one of (1) the reaction gas supply line and (2) the reaction gas supply module.

### Advantageous Effects

According to embodiments of the present disclosure, an atomic layer depositing apparatus and an atomic layer depositing method using the same, which can deposit an atomic layer of a high quality on a substrate, can be provided.

### DESCRIPTION OF DRAWINGS

FIG. 1 is a diagram showing the constitution of an atomic layer depositing apparatus according to an embodiment of the present disclosure.

FIGS. 2 to 7 are diagrams showing a process in which an atomic layer is deposited on a substrate by the atomic layer depositing apparatus of FIG. 1.

FIG. 8 is a diagram showing an atomic layer depositing apparatus according to another embodiment of the present disclosure.

FIG. 9 is a diagram showing an atomic layer depositing apparatus according to still another embodiment of the present disclosure.

FIG. 10 is a diagram showing an atomic layer depositing apparatus according to yet another embodiment of the present disclosure.

FIG. 11 is a diagram showing an atomic layer depositing apparatus according to still yet another embodiment of the present disclosure.

### BEST MODE FOR INVENTION

The advantages and features of the present disclosure and methods for achieving the advantages and features will be apparent by referring to the embodiments to be described in detail with reference to the accompanying drawings. However, the present disclosure is not limited to the embodiments disclosed hereinafter, and it will be implemented in various different forms. However, the embodiments are provided to complete the present disclosure and to assist those of ordinary skill in the art in a comprehensive understanding of the scope of the technical idea, and the disclosure is only defined by the scope of the appended claims.

Although the terms “first”, “second”, and so forth are used to describe various constituent elements, these constituent elements should not be limited by the terms. The above-described terms are used only for the purpose of discriminating one constituent element from another constituent element. Accordingly, a first constituent element to be mentioned hereinafter may be a second constituent element in the technical idea of the present disclosure.

Throughout the specification, the same reference numerals refer to the same constituent elements.

Respective features of several embodiments of the present disclosure can be linked to or combined with each other partially or entirely, and as can be fully understood by those skilled in the art, various technical interconnections and operations thereof are possible, and the embodiments can be implemented independently of each other or can be implemented together in association with each other.

Meanwhile, since the tentative effects that can be expected by the technical features of the present disclosure that are not specifically mentioned in the specification of the present disclosure may be treated as those described in the specification, and the present embodiment is provided to explain the present disclosure more completely to a person with average knowledge in the art, the contents illustrated in the drawings may be expressed exaggeratedly as compared to the actual implementation of the present disclosure, and the detailed explanation of the constitutions that may be determined to unnecessarily obscure the gist of the present disclosure will be omitted or will be briefly described.

Hereinafter, embodiments of the present disclosure will be described in detail with reference to the accompanying drawings.

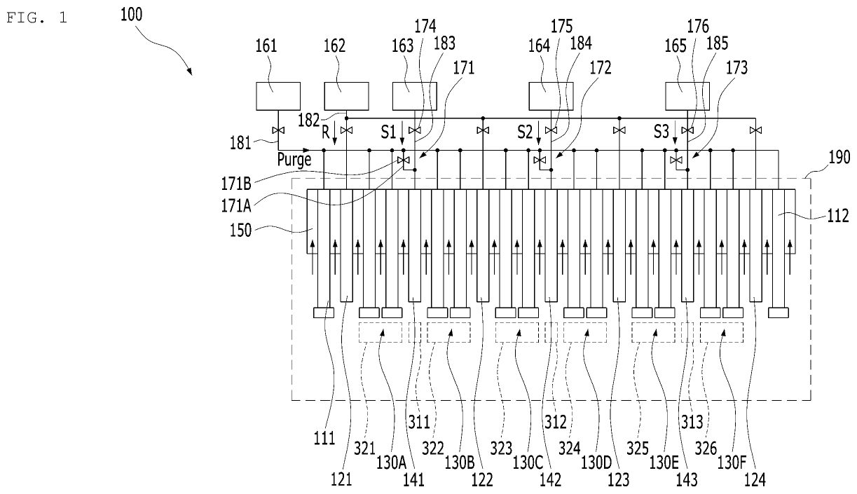

FIG. 1 is a diagram showing the constitution of an atomic layer depositing apparatus according to an embodiment of the present disclosure.

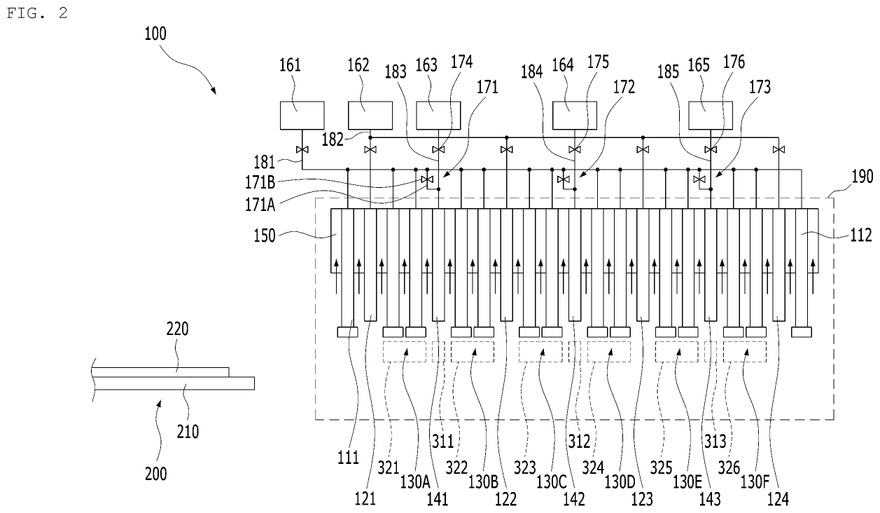

Referring to FIG. 1, an atomic layer depositing apparatus according to an embodiment of the present disclosure is a space division type atomic layer depositing apparatus, in which a substrate 220 (refer to FIG. 2) on which an atomic layer is deposited moves in one direction (first direction) or in the other direction (second direction) that is opposite to the first direction in a chamber area 190 in which a gas supply assembly 100 for supplying a source gas, a reaction gas, and a purge gas is disposed, and the atomic layer is deposited. For example, the substrate 220 may be a semiconductor substrate or a glass substrate, and the atomic layer may be deposited on one surface of the substrate 220. Meanwhile, the constitution in which the atomic layer is deposited on both surfaces of the substrate 220 may also be included in an embodiment of the present disclosure.

According to an embodiment of the present disclosure, since the supply of the source gas and the purge gas is controlled in accordance with an entrance location of the substrate 220, it is possible to suppress the deposition quality deterioration of the atomic layer due to an unintended diffusion of the source gas. Further, by providing various kinds of source gases, an atomic layer depositing apparatus capable of performing multicomponent atomic layer deposition, such as indium gallium zinc oxide (IGZO) can be provided.

Meanwhile, the atomic layer depositing apparatus according to an embodiment of the present disclosure may be driven in an atmosphere pressure state where an inert gas is filled in the chamber area 190. However, the constitution in which the operating pressure of the chamber area 190 of the atomic layer depositing apparatus is the atmosphere pressure is merely an exemplary constitution, and the constitution in which the chamber area 190 is in a vacuum state or in a low pressure state may also be included in the idea of the present disclosure.

Hereinafter, the constitution of the atomic layer depositing apparatus according to an embodiment of the present disclosure will be described in more detail.

The atomic layer depositing apparatus according to an embodiment of the present disclosure includes: a gas supply assembly 100 configured to supply a source gas, a reaction gas, and a purge gas; and a substrate transfer module 200 disposed on a lower side of the gas supply assembly 100, configured to move linearly, and having an upper side on which the substrate 220 is seated.

More specifically, the gas supply assembly 100 includes purge gas supply modules 111, 112, and 130A to 130F connected to a purge gas supply line 181 in which the purge gas flows, reaction gas supply modules 121, 122, 123, and 124 connected to a reaction gas supply line 182 in which the reaction gas flows, source gas supply modules 141, 142, and 143 configured to selectively communicate with any one of the purge gas supply line 181 and source gas supply lines 183, 184, and 185 in which the source gas flows, pumping modules 150 disposed among the purge gas supply modules 111, 112, and 130A to 130F, the reaction gas supply modules 121, 122, 123, and 124, and the source gas supply modules 141, 142, and 143, and configured to provide negative pressure, valve modules 171, 172, 173, 174, 175, and 176 configured to make the source gas supply modules connected to any one of the purge gas supply line and the source gas supply lines 183, 184, and 185 and blocked from the other thereof, and a valve module controller (not illustrated) configured to control the valve modules. Further, the atomic layer depositing apparatus according to an embodiment of the present disclosure includes a purge gas storage 161 connected to the purge gas supply line 181 and configured to supply the purge gas, and a reaction gas storage 162 connected to the reaction gas supply line 182 and configured to supply the reaction gas. The pumping modules 150 are connected to a pumping device (not illustrated) configured to provide a negative pressure, and make the reaction gas, the source gas, and the purge gas, being supplied from the modules, discharged to outside of the chamber area 190.

Further, the atomic layer depositing apparatus includes reaction gas storages 163, 164, and 165 connected to the source gas supply line 183, 184, and 185 and configured to supply the source gas. In this case, the reaction gases may be different kinds of reaction gases, and for example, the first reaction gas may include indium, the second reaction gas may include gallium, and the third reaction gas may include zinc. Further, the first reaction gas is stored in the first reaction gas storage 163, the second reaction gas is stored in the second reaction gas storage 164, and the third reaction gas is stored in the third reaction gas storage 165.

Meanwhile, in accordance with the location of the substrate 220, (1) in case that the substrate 220 is disposed on the side of the source gas supply modules 141, 142, and 143, the valve modules 171, 172, 173, 174, 175, and 176 according to an embodiment of the present disclosure are configured to supply the source gas by connecting the source gas supply modules 141, 142, and 143 and the source gas supply lines 183, 184, and 185 to each other. Further, (2) in case that the substrate 220 is not disposed on the side of the source gas supply modules 141, 142, and 143, the valve modules 171, 172, 173, 174, 175, and 176 are configured to supply the purge gas by connecting the source gas supply modules 141, 142, and 143 and the purge gas supply line 181 to each other. In this case, the valve module controller controls the operations of the valve modules 171, 172, 173, 174, 175, and 176 based on at least one of a location in the first direction of the substrate transfer module 200, a location where the substrate 220 is disposed on the substrate transfer module 200, and a transfer speed of the substrate transfer module 200.

The valve modules 171, 172, 173, 174, 175, and 176 include a bypass line 171A having one side connected to the source gas supply lines 183, 184, and 185 and the other side communicating with the purge gas supply line 181, a first valve unit 171B disposed on the bypass line 171A, and second valve modules 174, 175, and 176 disposed on the source gas supply lines 183, 184, and 185. The second valve modules 174, 175, and 176 are disposed between points where the source gas supply lines 183, 184, and 185 and the bypass line 171A are connected to each other and source gas storages 163, 164, and 165.

That is, in case that the first source gas supply module 141 supplies the source gas in accordance with the location of the substrate 220, the first valve unit 171B of the first valve modules 171 and 174 blocks the bypass line 171A, and the second valve module 174 opens the source gas supply line 183, so that the source gas is supplied from the first source gas supply module 141. In contrast, in case that the first source gas supply module 141 supplies the purge gas, the first valve unit 171B of the first valve modules 171 and 174 opens the bypass line 171A, and the second valve module 174 blocks the source gas supply line 183, so that the purge gas is supplied from the first source gas supply module 141.

In case that the substrate 220 is not located, the atomic layer depositing apparatus according to an embodiment of the present disclosure ensures that the source gas is not supplied, but the purge gas that is an inert gas, for example, such as nitride or argon, is supplied, so that unintended diffusion of the purge gas can be prevented, and thus the high-quality atomic layer can be deposited. Further, the atomic layer depositing apparatus 1 has the advantage of saving the source gas usage.

Meanwhile, the purge gas supply modules 111, 112, and 130A to 130F include a first side purge gas supply module 111 and a second side purge gas supply module 112 disposed on one side and the other side of the gas supply assembly 100, respectively, based on the first direction that is the transfer direction of the substrate 220, and main purge gas supply modules 130A to 130F disposed between the reaction gas supply modules 121, 122, 123, and 124 and the source gas supply modules 141, 142, and 143.

The main purge gas supply modules 130A to 130F include a first main purge gas supply unit 131 and a second main purge gas supply unit 132 connected to the purge gas supply line 181, respectively. The first main purge gas supply unit 131 and the second main purge gas supply unit 132 are spaced apart from each other based on the first direction, and the pumping module 150 is disposed between the first main purge gas supply unit 131 and the second main purge gas supply unit 132. In the present embodiment, the main purge gas supply modules 130A to 130F include a pair of main purge gas supply units 131 and 132, and enable the shielding between a reaction gas deposition area and a source gas deposition area to be performed more efficiently and smoothly.

The side purge modules 111 and 112 allow the deposition space formed on the lower side of the gas supply assembly 100 and the remaining chamber area to be separated from each other through the discharge of the purge gas.

The side purge modules 111 and 112 include a side purge gas supply unit through which the purge gas is discharged. One side purge gas supply unit may be provided for the side purge modules 111 and 112, and the pumping modules 150 are disposed in the front and rear of the side purge modules 111 and 112.

Meanwhile, a first supply pressure of the purge gas that is supplied from the side purge gas supply modules 111 and 112 may be formed differently from a second supply pressure of the purge gas that is supplied from the main purge gas supply modules 130A to 130F. For example, the second supply pressure of the main purge gas supply modules 130A to 130F for the purpose of blocking the diffusion between the source gas and the reaction gas may be formed to be smaller than the first supply pressure of the side purge gas supply modules 111 and 112 that supply the purge gas into an entrance area and an exit area for the deposition space. In case that the atomic layer depositing apparatus performs the atomic layer deposition under an atmosphere pressure condition, a greater supply pressure of the side purge gas supply modules 111 and 112 is provided to block the flow between the deposition space and the outside.

Further, the second supply pressure is constant regardless of the movement of the substrate, and the first supply pressure is varied in accordance with the location of the substrate 230. More specifically, if the substrate 230 enters the deposition space, the first supply pressure of the side purge modules 111 and 112 is formed greater than the first supply pressure of the side purge modules 111 and 112 and thus the deposition space and the chamber area can be divided more smoothly, in case that the substrate 230 has completely entered the deposition space or has completely seceded from the deposition space.

Meanwhile, a plurality of source gas supply modules 141, 142, and 143 and a plurality of reaction gas supply modules 121, 122, 123, and 124 are provided to be disposed alternately. For example, the reaction gas supply modules 121, 122, 123, and 124 include the first reaction gas supply module 121, the second reaction gas supply module 122, the third reaction gas supply module 123, and the fourth reaction gas supply module 124, the reaction gas may be, for example, oxygen, and the reaction gases being discharged from the first reaction gas supply module 121, the second reaction gas supply module 122, the third reaction gas supply module 123, and the fourth reaction gas supply module 124 are the same. Further, the source gas supply modules 141, 142, and 143 include the first source gas supply module 141 that discharges the first source gas, the second source gas supply module 142 that discharges the second source gas, and the third source gas supply module 143 that discharges the third source gas.

In this case, the first reaction gas supply module 121 that is adjacent to one side of the gas supply assembly 100 is disposed between the first main purge gas supply module 130A that is adjacent to the first side purge gas supply module 111 and the first side purge gas supply module 111. Further, the second reaction gas supply module 122 that is adjacent to the other side of the gas supply assembly 100 is disposed between the sixth main purge gas supply module 130F that is adjacent to the second side purge gas supply module 112 and the second side purge gas supply module 112.

In this case, the substrate transfer module 200 may selectively move in accordance with any one of the first direction and the second direction that is the direction opposite to the first direction in a state where the substrate 220 is seated on a substrate transfer module body 210.

In the atomic layer depositing apparatus according to the present embodiment, the substrate 220 moves in any one of the first direction and the second direction, and the atomic layer is deposited on an upper surface of the substrate 220. In this case, in a state where the substrate 220 has completely seceded from the deposition space after the atomic layer deposition process is performed while the substrate 220 moves in the first direction, the atomic layer deposition process may be performed as the substrate 220 moves again in the second direction. In the present embodiment, since the reaction gas supply modules 121 and 124 are disposed on one side and the other side of the gas supply assembly 100, the source gas and the reaction gas react smoothly during such a reciprocating motion, and thus the atomic layer deposition efficiency can be increased.

Between the first source gas supply module 141 and the second source gas supply module 142 among the source gas supply modules 141, 142, and 143, the pumping modules 150, the main purge gas supply modules 130A and 130A, and the reaction gas supply modules 122 are disposed.

In this case, the pumping modules 150, the main purge gas supply modules 130A and 130A, and the reaction gas supply modules 122 are disposed in the order of “the pumping module 150—the second main purge gas supply module 130B—the pumping module 150—the second reaction gas supply module 122—the pumping module 150—the third main purge gas supply module 130C—the pumping module 150”.

In this case, the source gas includes a first source gas (e.g., source gas including indium) and a second source gas (e.g., source gas including gallium) having a different material from the first source gas. The first source gas supply module 141 is selectively connected to the first source gas supply line 183 for supplying the first source gas, and the second source gas supply module 142 is selectively connected to the second source gas supply line 184 for supplying the second source gas. In this case, the first reaction gas supply module 121 is disposed between the first side purge gas supply module 111 and the first main purge gas supply module 130A, and the first main purge gas supply module 130A is disposed between the first reaction gas supply module 121 and the first source gas supply module 141.

Meanwhile, sine the disposition constitution between the second source gas supply module 142 and the third source gas supply module 143 is substantially the same as the disposition constitution between the second source gas supply module 142 and the third source gas supply module 143, the detailed explanation thereof will be omitted.

Further, for example, the second purge gas supply module 130B, the source gas deposition space 311, 312, or 313, for example, the first source gas deposition space 311, is formed between any one of the purge gas supply modules 130A to 130F, for example, the first main purge gas supply module 130A, which is disposed in front of any one source gas supply module 141, 142, or 143, for example, the first source gas supply module 141, based on the first direction, and another purge gas supply module 130A to 130F, for example, the second purge gas supply module 130B, which is disposed in the rear of the first source gas supply module 141.

If one side of the substrate 220 enters the first source gas deposition space 311, the first valve modules 171 and 174 are controlled so that the first source gas supply module 141 that corresponds to the first source gas deposition space 311 supplies the source gas. Further, if the other side of the substrate 220 secedes from the first source gas deposition space 311, the valve modules 171 and 174 are controlled so that the first source gas supply module 141 that corresponds to the first source gas deposition space 311 supplies the purge gas.

In this case, the source gas deposition spaces 311, 312, and 313 include the first source gas deposition space 311, the second source gas deposition space 312, and the third source gas deposition space 313, and the plurality of source gas deposition spaces 311, 312, and 313 are disposed to be spaced apart from each other in accordance with the first direction.

Between the reaction gas supply modules 121, 122, 123, and 124 and the source gas supply modules 141, 142, and 143 adjacent to the reaction gas supply modules 121, 122, 123, and 124, purge spaces 321, 322, 323, 324, 325, and 326, in which the purge gas is supplied onto the substrate, are formed, and the purge spaces 321, 322, 323, 324, 325, and 326 may be formed larger than the source gas deposition spaces 311, 312, and 313 based on the first direction.

Since the purge spaces 321, 322, 323, 324, 325, and 326 are formed with a larger size than the size of the source gas deposition spaces 311, 312, and 313, it is possible to efficiently suppress the inflow of the source gas to an adjacent area in which other gases flow in the deposition space.

In this case, the width in the first direction of a head part of the purge gas supply modules 130A to 130F is set to be larger than the width in the first direction of a head part of the source gas deposition modules 141, 142, and 143.

Meanwhile, unlike the source gas supply modules 141, 142, and 143, the reaction gas supply modules 121, 122, 123, and 124 and the purge gas supply modules 111, 112, and 130A to 130F continuously supply the reaction gas and the purge gas, respectively, regardless of the location of the substrate 220.

Hereinafter, an atomic layer depositing method using the atomic layer depositing apparatus according to an embodiment of the present disclosure will be described in detail.

FIGS. 2 to 7 are diagrams showing a process in which an atomic layer is deposited on a substrate by the atomic layer depositing apparatus of FIG. 1.

First, referring to FIG. 2, in case that the substrate 220 exists outside the deposition space, the reaction gas supply modules 121, 122, 123, and 124 supply the reaction gas, and the purge gas supply modules 111, 112, and 130A to 130F and the source gas deposition modules 141, 142, and 143 supply the purge gas. The pumping module 150 continuously provides a negative pressure, and discharges the gases out of the deposition space.

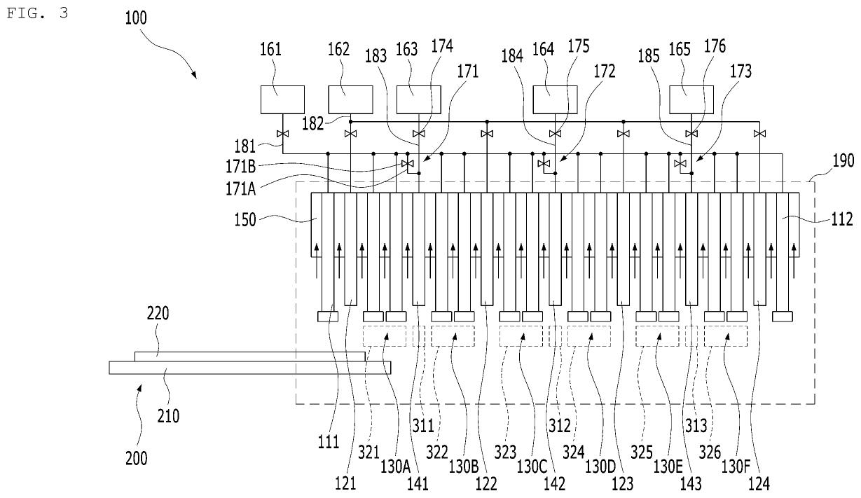

Then, referring to FIG. 3, in case that the substrate 220 has entered the deposition space through movement in the first direction, but one side of the substrate 220 is located in the first purge space 322 and has not yet entered the first source gas deposition space 311, the reaction gas supply modules 121, 122, 123, and 124 supply the reaction gas, and the purge gas supply modules 111, 112, and 130A to 130F and the source gas deposition modules 141, 142, and 143 maintain the supply of the purge gas.

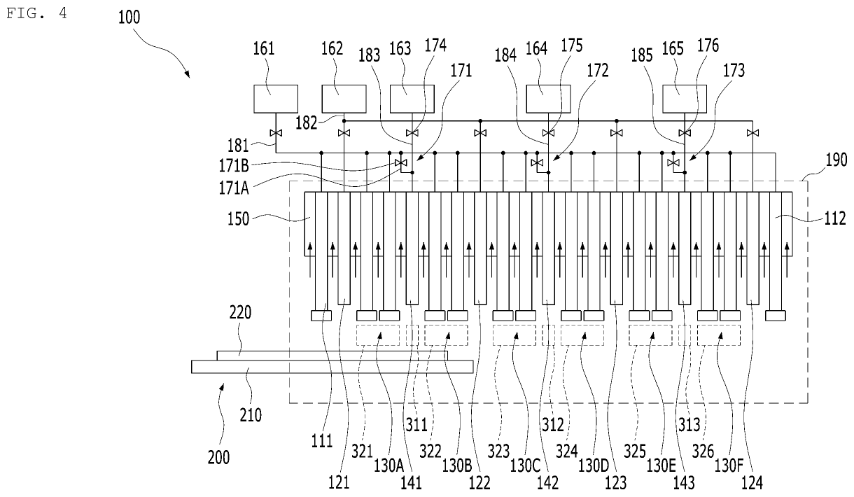

Then, referring to FIG. 4, if the one side of the substrate 220 has entered the first source gas deposition space 311 through movement in the first direction, the first source gas deposition module 141 blocks the supply of the purge gas, and starts the supply of the first source gas. In this case, the reaction gas supply modules 121, 122, 123, and 124 supply the reaction gas, and the purge gas supply modules 111, 112, and 130A to 130F and the remaining source gas deposition modules 142 and 143 supply the purge gas.

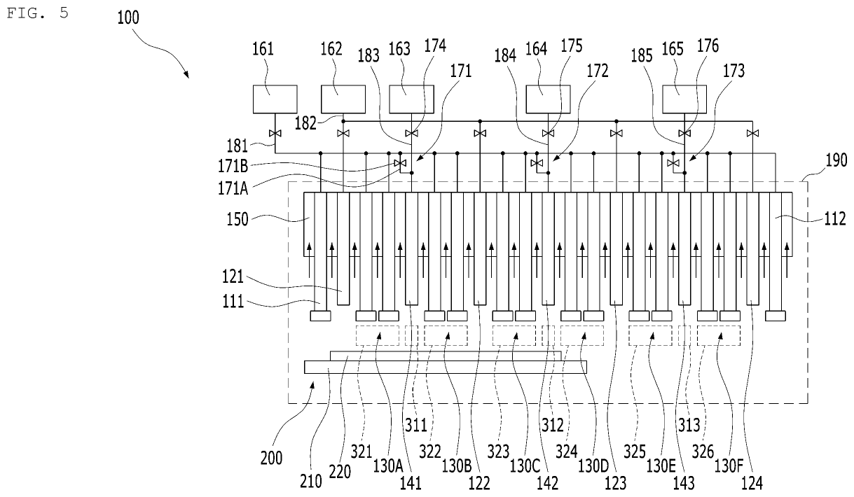

Then, referring to FIG. 5, if the one side of the substrate 220 enters the second source gas deposition space 312, the second source gas deposition module 142 blocks the supply of the purge gas, and starts the supply of the second source gas. In this case, on one side of the substrate 220 is formed a first reaction layer that is formed through mutual reaction of the first source gas deposited while passing through the first source gas deposition space 311 and the reaction gas deposition space and the reaction gas.

In this case, the other side of the substrate 220 is in a state where it has not yet entered the first source gas deposition space 311, and the first source gas deposition module 141 maintains the supply of the first source gas. Until the other side of the substrate 220 secedes from the first source gas deposition space 311 toward the first direction, the first source gas deposition module 141 continuously performs the supply of the first source gas.

Further, the reaction gas supply modules 121, 122, 123, and 124 supply the reaction gas, and the purge gas supply modules 111, 112, and 130A to 130F and the third source gas deposition modules 142 and 143 supply the purge gas to the deposition space.

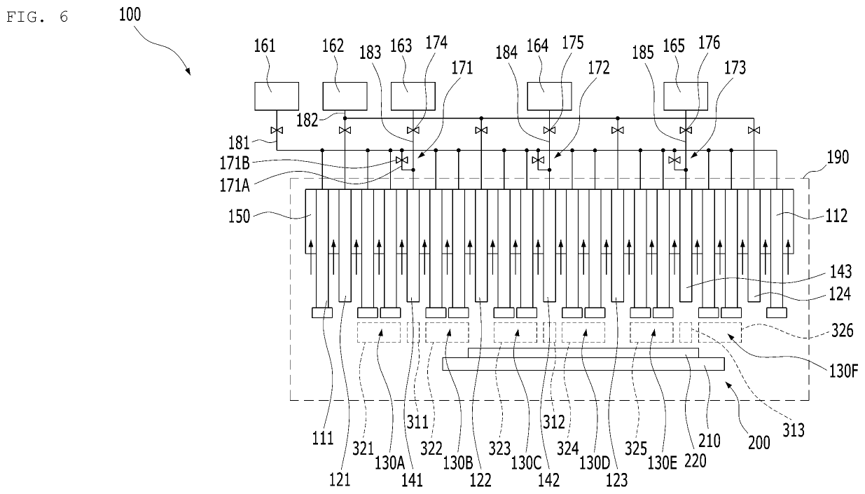

Then, referring to FIG. 6, the one side of the substrate 220 has entered the third source gas deposition space 313, and the other side of the substrate 220 completely secedes from the first source gas deposition space 311.

In this case, if the one side of the substrate 220 has entered the third source gas deposition space 313, the third source gas deposition module 143 blocks the supply of the purge gas, and starts the supply of the third source gas.

Further, if the other side of the substrate 220 secedes from the first source gas deposition space 311 in the first direction, the first source gas deposition module 141 blocks the supply of the first source gas, and starts the supply of the purge gas.

In this case, the second source gas deposition module 142 still supplies the second source gas to the second source gas deposition space 312 of the deposition space.

Further, the reaction gas supply modules 121, 122, 123, and 124 supply the reaction gas, and the purge gas supply modules 111, 112, and 130A to 130F supply the purge gas.

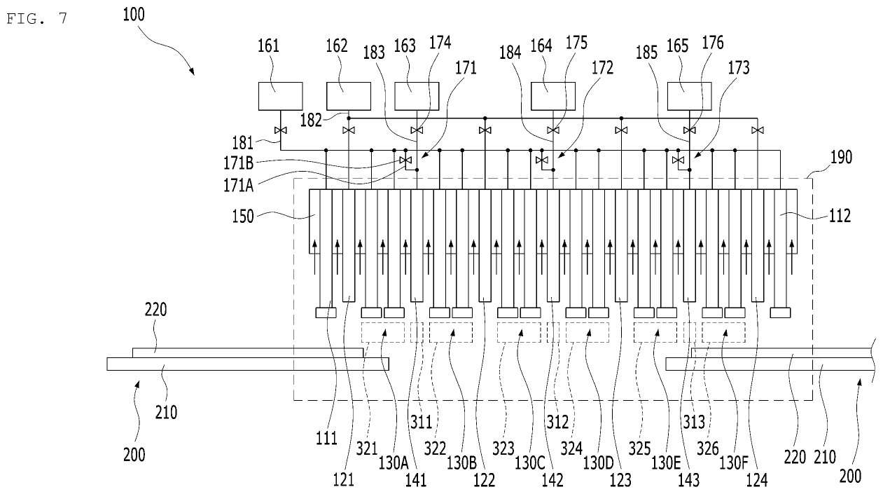

Then, referring to FIG. 7, in case that the plurality of substrates 220 are located in the deposition space that is formed on the lower side of the gas supply assembly 100, the atomic layer depositing apparatus according to the present embodiment allows the source gas supply modules 141, 142, and 143 of the source gas deposition spaces 311, 312, and 313 in which the substrates 220 are located to supply the source gas to the source gas deposition spaces 311, 312, and 313, and allows the source gas supply modules 141, 142, and 143 of the source gas deposition spaces 311, 312, and 313 in which the substrates 220 are not located to supply the purge gas to the source gas deposition spaces 311, 312, and 313.

That is, the source gas supply modules 141, 142, and 143 on which the substrate 220 is located supply the source gas, and the source gas supply modules 141, 142, and 143 on which the substrate 220 is not located supply the purge gas.

TABLE 1

| End | First | | | | |
|---|---|---|---|---|---|
| position | substrate | | | | |
| of first | end | First | Second | Third | Reaction |
| substrate | position | source | source | source | gas |
| (Forward | (Rearward | gas (S₁) | gas (S₂) | gas (S₃) | (S₁) |
| (One | (The other | (Ex.) | (Ex.) | (Ex.) | (Ex.) |
| side)) | side)) | Indium | Gallium | Zinc | Oxygen |
| Outside | Outside | X(Purge) | X(Purge) | X(Purge) | ◯ |
| First | Outside | ◯ | X(Purge) | X(Purge) | ◯ |
| source gas | | | | | |
| deposition | | | | | |
| space (311) | | | | | |
| Second | Outside | ◯ | ◯ | X(Purge) | ◯ |
| source gas | | | | | |
| deposition | | | | | |
| space(312) | | | | | |
| Third | Second | X(Purge) | ◯ | ◯ | ◯ |
| source gas | purge | | | | |
| deposition | space(321) | | | | |
| space(313) | | | | | |
| Outside | Third | ◯(End | X | ◯ | ◯ |
| | source gas | part of one | | | |
| | deposition | side of | | | |
| | space(313) | second | | | |
| | | substrate) | | | |

In Table 1, a control table of the atomic layer depositing apparatus is illustrated.

As shown in Table 1, a valve controller of the atomic layer depositing apparatus according to an embodiment of the present disclosure controls the valve modules 171, 172, 173, 174, 175, and 176 based on a data table for end locations on one side and the other side of the substrate 220.

According to the proposed embodiment, in the space division type atomic layer depositing apparatus, the source gas supply modules 141, 142, and 143 on which the substrate 220 is not located supply the purge gas, and only the source gas supply modules 141, 142, and 143 on which the substrate 220 is located supply the source gas, so that the leakage of the source gas to other areas of the deposition space can be suppressed.

Further, since the source gases including different materials are supplied during once movement of the substrate 220, the atomic layer depositing apparatus has the advantage of being able to form a multicomponent atomic layer.

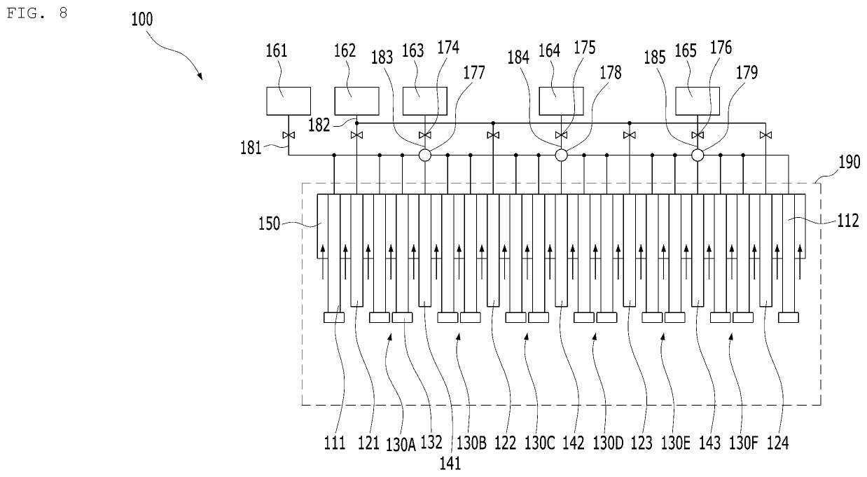

FIG. 8 is a diagram showing an atomic layer depositing apparatus according to another embodiment of the present disclosure.

Since the constitution of the present embodiment is substantially the same as the constitution of the atomic layer depositing apparatus and the atomic layer depositing method using the same as illustrated in FIGS. 1 to 7 although the only difference is in the constitution of the valve modules, explanation will be hereinafter made with a focus on the features of the present embodiment.

Referring to FIG. 8, the first source gas supply line 183, the second source gas supply line 184, and the third source gas supply line 185 are connected to the purge gas supply line 181, and the plurality of valve modules 177, 178, and 179 are installed at points where the source gas supply lines 183, 184, and 185 and the purge gas supply line 181 are connected to each other.

The plurality of valve modules 177, 178, and 179 allow only one gas to be selectively supplied to the side of the source gas supply modules 183, 184, and 185. For example, the valve modules 177, 178, and 179 may be flow path switching valves.

The present embodiment has the advantage of simplifying the constitution of the valve module.

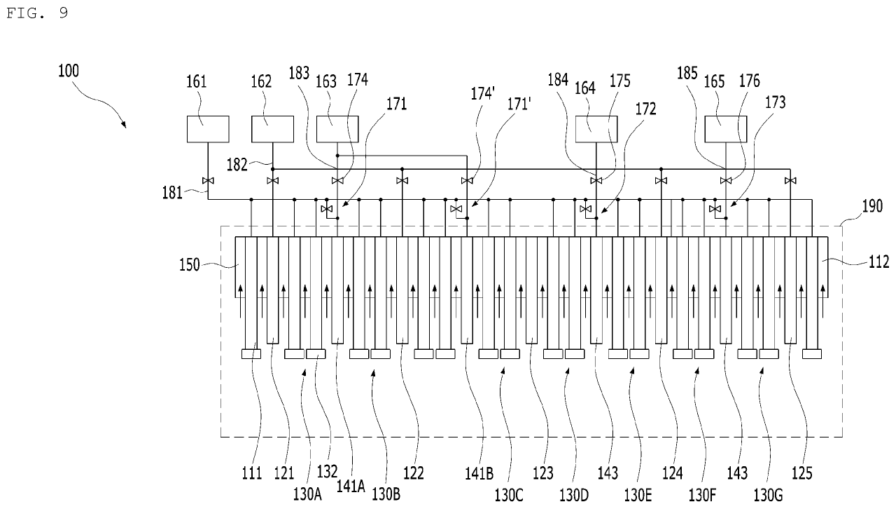

FIG. 9 is a diagram showing an atomic layer depositing apparatus according to still another embodiment of the present disclosure.

Since the constitution of the present embodiment is substantially the same as the constitution of the atomic layer depositing apparatus and the atomic layer depositing method using the same as illustrated in FIGS. 1 to 7 although the only difference is in the constitution of the source gas supply modules, explanation will be hereinafter made with a focus on the features of the present embodiment.

Referring to FIG. 9, the first source gas supply module 141 includes a first sub first source gas supply module 141A for supplying the first source gas and a second sub first source gas supply module 141B.

In this case, the first sub first source gas supply module 141A and the second sub first source gas supply module 141B are spaced apart from each other in the first direction, and between the first sub first source gas supply module 141B and the second sub first source gas supply module 141B, the pumping modules 150, the main purge gas supply modules 130B and 130C, and the reaction gas supply modules 122 are disposed, and are disposed in the order of “the pumping module 150—the second main purge gas supply module 130B—the pumping module 150—the second reaction gas supply module 122—the pumping module 150—the third main purge gas supply module 130C—the pumping module 150”.

In the present embodiment, for example, for one cycle when the substrate 220 is deposited while moving in the first direction, the first source gas is deposited twice, and the second source gas and the first source gas are deposited once. That is, by differently setting the number of times of depositions between different kinds of source gases, there is the advantage of being able to form the atomic layer of a desired physical property.

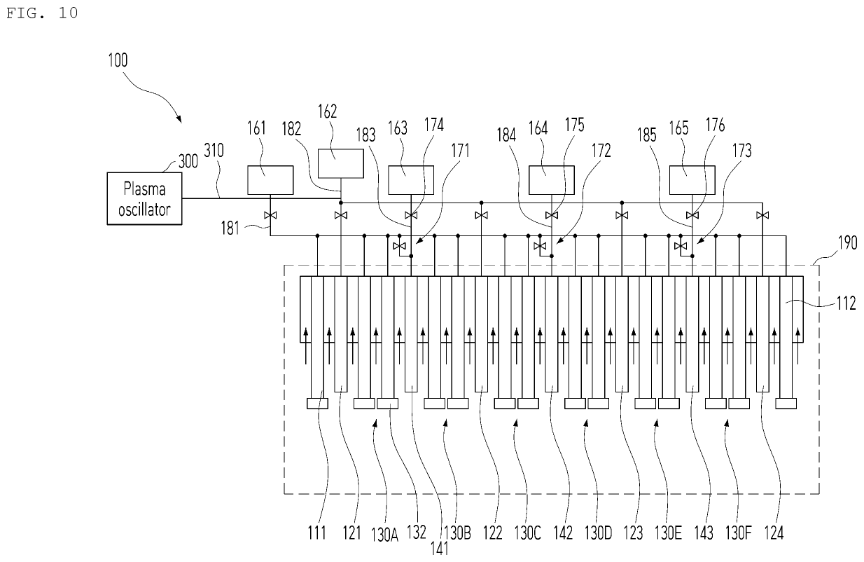

FIG. 10 is a diagram showing an atomic layer depositing apparatus according to yet another embodiment of the present disclosure.

Since the constitution of the present embodiment is substantially the same as the constitution of the atomic layer depositing apparatus and the atomic layer depositing method using the same as illustrated in FIGS. 1 to 7 although the only difference is in the constitution of the plasma oscillator, explanation will be hereinafter made with a focus on the features of the present embodiment.

Referring to FIG. 10, the atomic layer depositing apparatus according to an embodiment of the present disclosure further includes a plasma oscillator 300 configured to ionize the reaction gas.

The plasma oscillator 300 is connected to the reaction gas supply line 182, and is configured to ionize the reaction gas that is supplied from the reaction gas storage 162, and thus allows the reaction of the source gas and the reaction gas to be performed more actively.

Meanwhile, the plasma oscillator 300 may provide a pulse-shaped voltage, and may be connected between the junction of the reaction gas supply line 182 and the reaction gas storage 162.

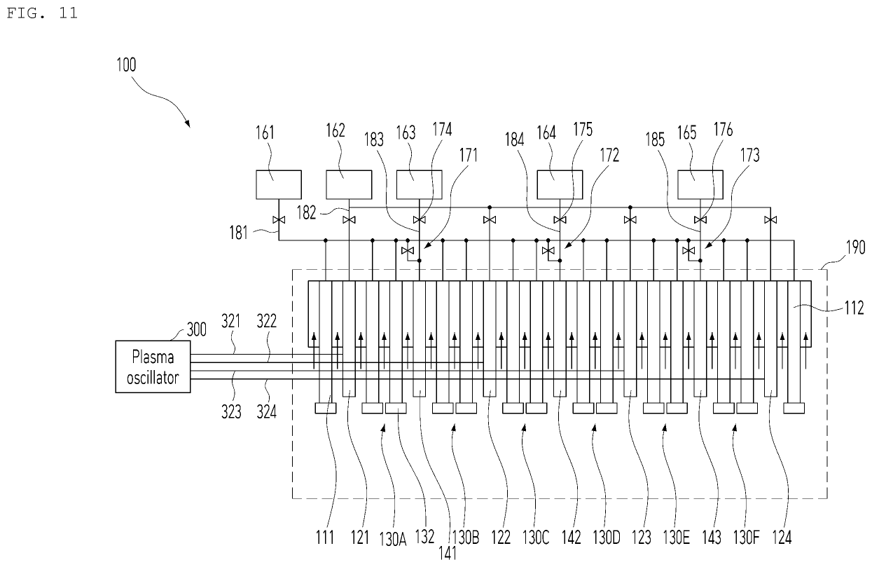

FIG. 11 is a diagram showing an atomic layer depositing apparatus according to still yet another embodiment of the present disclosure.

Since the constitution of the present embodiment is substantially the same as the constitution of the atomic layer depositing apparatus and the atomic layer depositing method using the same as illustrated in FIG. 10 although the only difference is in the constitution of the plasma oscillator, explanation will be hereinafter made with a focus on the features of the present embodiment.

Referring to FIG. 11, the plasma oscillator 300 may be connected to the reaction gas supply modules 121, 122, 123, and 124, and may ionize the reaction gas that flows in the reaction gas supply modules 121, 122, 123, and 124. That is, since the plasma oscillator 300 is directly connected to the reaction gas supply modules 121, 122, 123, and 124 that supply the reaction gas toward the upper surface of the substrate 220, and supply the pulse-shaped voltage, the ionization efficiency of the reaction gas can be improved.

As described above, although preferred embodiments of the present disclosure have been described, the present disclosure is not limited thereto, and it will be apparent that various modifications are possible within the range of the claims, the detailed description of the present disclosure, and the accompanying drawings, and of course, they also belong to the scope of the present disclosure.

### MODE FOR INVENTION

The mode for the present disclosure has been described together in the best mode for the present disclosure as above.

### INDUSTRIAL APPLICABILITY

The present disclosure relates to an atomic layer depositing apparatus and an atomic layer depositing method using the same, and has the repeatability and industrial applicability in an atomic layer depositing apparatus and the like.

What is claimed is:

1. An atomic layer depositing apparatus comprising:
a gas supply assembly configured to supply a source gas, a reaction gas, and a purge gas; and
a substrate transfer module disposed on a lower side of the gas supply assembly, configured to move linearly, and having an upper side on which the substrate is seated,
wherein the gas supply assembly includes: a purge gas supply module connected to a purge gas supply line in which the purge gas flows, a reaction gas supply module connected to a reaction gas supply line in which the reaction gas flows, a source gas supply module configured to selectively communicate with any one of the purge gas supply line and a source gas supply line in which the source gas flows, a pumping module disposed among the purge gas supply module, the reaction gas supply module, and the source gas supply module, and configured to provide negative pressure, and a valve module configured to make the source gas supply module connected to any one of the purge gas supply line and the source gas supply line and blocked from the other thereof, and
wherein the valve module is configured to: (1) connect the source gas supply module and the source gas supply line to each other in case that the substrate is disposed on the side of the source gas supply module, and (2) connect the source gas supply module and the purge gas supply line to each other in case that the substrate is not disposed on the side of the source gas supply module.

2. The apparatus of claim 1, wherein the purge gas supply module comprises a first side purge gas supply module and a second side purge gas supply module disposed on one side and the other side of the gas supply assembly, respectively, based on a first direction that is a transfer direction of the substrate, and main purge gas supply modules disposed between the reaction gas supply module and the source gas supply module, and
wherein a plurality of source gas supply modules and a plurality of reaction gas supply modules are provided to be disposed alternately.

3. The apparatus of claim 2, wherein the main purge gas supply module comprises a first main purge gas supply unit and a second main purge gas supply unit connected to the purge gas supply line, respectively, and
wherein the first main purge gas supply unit and the second main purge gas supply unit are spaced apart from each other based on the first direction, and the pumping module is disposed between the first main purge gas supply unit and the second main purge gas supply unit.

4. The apparatus of claim 3, wherein the side purge module comprises a side purge gas supply unit from which the purge gas is discharged,
wherein a first supply pressure of the purge gas that is supplied from the side purge gas supply unit is formed differently from a second supply pressure of the purge gas that is supplied from the main purge gas supply unit, and
wherein the second supply pressure is constant regardless of movement of the substrate, and the first supply pressure is varied in accordance with a location of the substrate.

5. The apparatus of claim 2, wherein any one of the reaction gas supply modules is disposed between the main purge gas supply module adjacent to the first side purge gas supply module among the main purge gas supply modules and the first side purge gas supply module,
wherein the other of the reaction gas supply modules is disposed between the main purge gas supply module adjacent to the second side purge gas supply module among the main purge gas supply modules and the second side purge gas supply module, and
wherein the substrate transfer module selectively moves in accordance with any one of the first direction and a second direction that is a direction opposite to the first direction.

6. The apparatus of claim 2, wherein between a first source gas supply module that is any one of the source gas supply modules and a second source gas supply module that is the other of the source gas supply modules, the pumping modules, the main purge gas supply modules, and the reaction gas supply modules are disposed, in the order of “the pumping module—the main purge gas supply module—the pumping module—the reaction gas supply module—the pumping module—the main purge gas supply module—the pumping module”.

7. The apparatus of claim 6, wherein the source gas comprises a first source gas and a second source gas having a different material from the first source gas,
wherein the first source gas supply module is selectively connected to a first source gas supply line for supplying the first source gas, and
wherein the second source gas supply module is selectively connected to a second source gas supply line for supplying the second source gas.

8. The apparatus of claim 7, wherein the first source gas supply module comprises a first sub first source gas supply module for supplying the first source gas and a second sub first source gas supply module,
wherein the first sub first source gas supply module and the second sub first source gas supply module are spaced apart from each other in the first direction, and
wherein between the first sub first source gas supply module and the second sub first source gas supply module, the pumping modules, the main purge gas supply modules, and the reaction gas supply modules are disposed, in the order of “the pumping module—the main purge gas supply module—the pumping module—the reaction gas supply module—the pumping module—the main purge gas supply module—the pumping module”.

9. The apparatus of claim 7, wherein the same reaction gas is supplied to the plurality of reaction gas supply modules, and
wherein the same purge gas is supplied to the plurality of purge gas supply modules.

10. The apparatus of claim 1, wherein a source gas deposition space is formed between any one of the purge gas supply modules that is disposed in front of any one of the source gas supply modules and the other of the purge gas supply modules that is disposed in the rear of the source gas supply module based on a first direction,
wherein if one side of the substrate enters the source gas deposition space, the valve module is controlled so that the source gas supply module that corresponds to the source gas deposition space supplies the source gas, and
wherein if the other side of the substrate secedes from the source gas deposition space, the valve module is controlled so that the source gas supply module that corresponds to the source gas deposition space supplies the purge gas.

11. The apparatus of claim 10, further comprising a valve module controller for controlling the valve module,
wherein the valve module controller is configured to control an operation of the valve module based on at least one of a location in the first direction of the substrate transfer module, a location where the substrate is disposed on the substrate transfer module, and a transfer speed of the substrate transfer module.

12. The apparatus of claim 11, wherein a plurality of source gas deposition spaces are formed and disposed to be spaced apart from each other in the first direction, and
wherein in case that a plurality of substrates are located in a deposition space that is formed on a lower side of the gas supply module, the source gas supply module in the source gas deposition space in which the substrates are located is configured to supply the source gas into the source gas deposition space, and the source gas supply module in the source gas deposition space in which the substrates are not located is configured to supply the purge gas into the source gas deposition space.

13. The apparatus of claim 12, wherein the reaction gas supply module and the purge gas supply module are configured to continuously supply the reaction gas and the purge gas regardless of the location of the substrate.

14. The apparatus of claim 10, wherein a purge space in which the purge gas is supplied to the substrate is formed between the reaction gas supply module and the source gas supply module that is adjacent to the reaction gas supply module, and the purge space is formed larger than the source gas deposition space based on the first direction.

15. The apparatus of claim 1, wherein the valve module comprises a bypass line having one side connected to the source gas supply line and the other side connected to the purge gas supply line, a first valve unit disposed on the bypass line, and a second valve unit disposed on the source gas supply line, and
wherein the second valve unit is disposed between a point where the source gas supply line and the bypass line are connected to each other and a source gas storage in which the source gas is stored.

16. The apparatus of claim 1, wherein the source gas supply line and the purge gas supply line are connected to each other, and
wherein the valve module is installed at a point where the source gas supply line and the purge gas supply line are connected to each other, and is configured to make any one of the gases be selectively supplied to the side of the source gas supply module.

17. The apparatus of claim 1, further comprising a plasma oscillator configured to ionize the reaction gas,
wherein the plasma oscillator is connected to any one of (1) the reaction gas supply line and (2) the reaction gas supply module.

18. An atomic layer depositing method using the atomic layer depositing apparatus of claim 1.
